(19) United States
(12) Patent Application Publication
(10) Pub. No.: US 2023/0138958 A1
(43) Pub. Date: May 4, 2023

(54) METHOD FOR TREATING A WAFER SURFACE

(71) Applicant: SHANGHAI INSTITUTE OF MICROSYSTEM AND INFORMATION TECHNOLOGY CHINESE ACADEMY OF SCIENCES, Shanghai (CN)

(72) Inventors: Xing Wei, Shanghai (CN); Rong Wang Dai, Shanghai (CN); Zi Wen Wang, Shanghai (CN); Zhong Ying Xue, Shanghai (CN); Meng Chen, Shanghai (CN); Hong Tao Xu, Shanghai (CN)

(73) Assignee: SHANGHAI INSTITUTE OF MICROSYSTEM AND INFORMATION TECHNOLOGY CHINESE ACADEMY OF SCIENCES, Shanghai (CN)

(21) Appl. No.: 17/585,549

(22) Filed: Jan. 27, 2022

(30) Foreign Application Priority Data
Oct. 29, 2021 (CN) 202111269451.1

(51) Int. Cl. H01L 21/324; H01L 21/02; H01L 21/311

(52) U.S. Cl. CPC H01L 21/324; H01L 21/02236; H01L 21/31111

(57) ABSTRACT

The present disclosure relates to a method for treating a wafer surface. By controlling the gas composition at each stage of the treatment process, and corresponding processes of heating and annealing, and cooling and thinning by oxidation, the final wafer is enabled to have a surface roughness of less than 5 Å. This effectively reduces the cost of the final treatment process and has good application prospects.

### CROSS-REFERENCE TO RELATED APPLICATION

This application claims the priority benefit of China application serial no. 202111269451.1, filed on Oct. 29, 2021. The entirety of the above-mentioned patent application is hereby incorporated by reference herein and made a part of this specification.

### BACKGROUND

### Technical Field

The present disclosure belongs to the field of silicon-on-insulators, and particularly relates to a method for treating wafer surface.

### Description of Related Art

As the post-Moore era marches on, more demanding requirements are put forward on semiconductor wafers, especially silicon wafers, in terms of structure, thickness homogeneity, surface smoothness, and other aspects. Nowadays, SOI (silicon on insulator) wafers have been widely used in the fields of microelectronics, optics and optoelectronics. This also correspondingly poses more challenges to the materials. It is required that the advanced SOI devices have a thinner top silicon layer, which directly exposes the shortcomings of the conventional chemical mechanical polishing method (for example, uneven thickness, and inclination of bringing in additional surface defects). The final-stage thermal treatment, including long-term thermal annealing and rapid thermal annealing, is reckoned as a favorable means for replacing the conventional chemical mechanical polishing method. The long-term thermal annealing can smooth out the long-range undulation (low frequency) of the wafer more easily, while the rapid thermal annealing has the advantage of flattening short-range undulation (high frequency), and the whole process is quick and saves time. The SOI thermal annealing process is generally carried out in an argon-hydrogen mixed atmosphere, wherein hydrogen mainly plays the role of preventing deterioration of surface granularity caused by the presence of oxygen. However, since hydrogen has an etching effect on the surface of silicon wafers under high temperatures, its content is critical. SOIs for specific purposes generally correspond to different thickness of top silicon layer. Therefore, it is necessary to integrate a thinning process following the thermal annealing process.

U.S. Pat. No. 9,202,711B2 discloses a method for reducing the free surface roughness of a semiconductor wafer, comprising processing a wafer, a silicon layer, and a dielectric layer between the wafer and the silicon layer. The silicon layer has a cleaved surface defining an outer surface of the structure. The method involves thermally annealing (for 1 hour to 4 hours) the structure in an environment comprising a gas (preferably from 5% to 7%) selected from the group consisting of argon, hydrogen, helium and mixtures thereof at a temperature of at least about 950° C. (preferably 1050° C. to 1200° C.), and then performing a non-contact smoothing process on the cleaved surface. However, during the whole smoothing process, if hydrogen is of an excessively high concentration in the hydrogen-argon mixture, it would cause etching on the wafer surface, thus making the final surface hardly meet the targeted state.

U.S. Pat. No. 8,389,412B2 reduces to some extent the surface roughness of a SOI wafer, by integrating rapid thermal annealing with thinning by oxidation, and finally processing the wafer through the RTA/Sacrox/RTA/Sacrox process. RTA can achieve the effect of reducing the surface roughness of the SOI wafer within a certain range, but the final roughness achieved by this process still cannot meet the current technical requirements, due to its limitations in dealing with low-frequency undulation.

### SUMMARY

The present disclosure provides a method for treating a wafer surface. By controlling the gas composition at each stage of the treatment process, and the corresponding processes of heating and annealing, and cooling and thinning by oxidation, the final wafer is enabled to have a surface roughness of less than 5 Å. This effectively reduces the cost of the final treatment process and has good application prospects.

The present disclosure provides a method for treating a wafer surface, including: loading a wafer with a SOI structure into a vertical furnace tube at a temperature of 500° C. to 800° C. (preferably 560° C.) in an atmosphere of pure Ar, and maintaining this for 1 min to 10 min (preferably 5 min); then switching the atmosphere to a mixed atmosphere of Ar+n % H₂ and starting to heat up, wherein n is less than 10 (preferably less than 3); increasing the temperature to a range of 1050° C. to 1250° C. (preferably from 1100° C. to 1200° C.) followed by annealing for 1 min to 120 min (preferably from 30 min to 60 min); maintaining the atmosphere to be pure Ar after the annealing process is completed, and taking out the wafer when the temperature is decreased to below 700° C.

The heating rate is 0.5° C./min to 20° C./min.

After the temperature is increased to a range of 1050° C. to 1250° C., the mixed atmosphere Ar+n % H₂ in the heating-up stage is maintained, or switched to a pure Ar atmosphere.

The cooling rate of decreasing the temperature to room temperature is 0.5° C./min to 10° C./min.

Optionally, thinning by oxidation is carried out after the annealing process is completed, and then the temperature is decreased to room temperature.

The oxidation temperature is in a range of 800° C. to 1000° C., and the cooling rate of decreasing the temperature to oxidation temperature is 1° C./min to 10° C./min.

The atmosphere for thinning by oxidation is dry oxygen, wet oxygen, or a combination of dry oxygen and wet oxygen.

Optionally, after thinning by oxidation is completed, the atmosphere is switched to pure Ar, and the temperature is slowly decreased to a range of 500° C. to 800° C., preferably 650° C., at the cooling rate of 0.5° C./min to 10° C./min.

Optionally, after thinning by oxidation, the surface oxidized layer is removed in a HF solution with a concentration of less than 20%.

By controlling the gas composition at each stage of the treatment process, and corresponding processes of heating and annealing, and cooling and thinning by oxidation, the final wafer is enabled to have a surface roughness of less than 5 Å. This effectively reduces the cost of the final treatment process and enjoys good application prospects.

### BRIEF DESCRIPTION OF THE DRAWINGS

FIG. 1 shows the temperature curve and atmosphere of the first process according to the present disclosure;

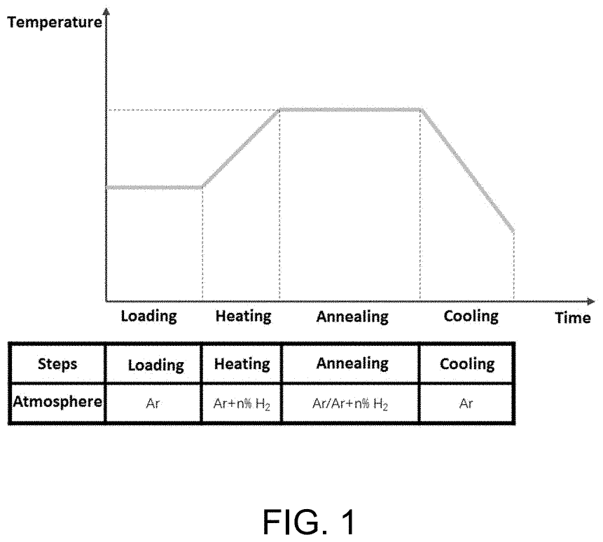

FIG. 2 shows the temperature curve and atmosphere of the second process according to the present disclosure;

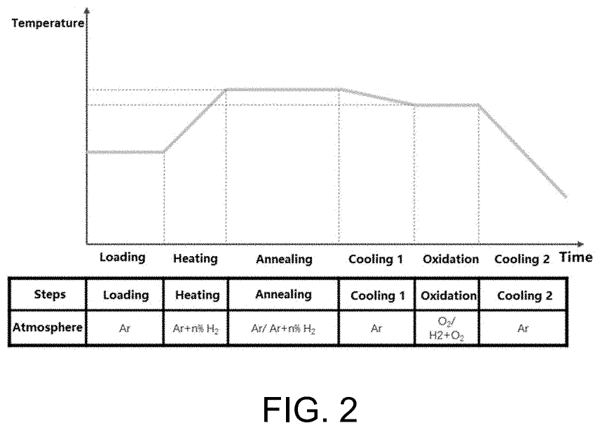

FIG. 3 shows a non-contact scanning image of a SOI wafer surface AFM 10 μm×10 μm before and after annealing in Example 1.

### DESCRIPTION OF THE EMBODIMENTS

The present disclosure is further described below in conjunction with specific Examples. It should be appreciated that these Examples are only used to illustrate the present disclosure rather than to limit the scope of the present disclosure. The method of the present disclosure is also applicable to other similar semiconductor materials. In addition, it should be appreciated that, upon reading the content taught by the present disclosure, a person skilled in the art can make various changes or modifications to the present disclosure, and these equivalents also fall within the scope defined by the appended claims of the present application.

### EXAMPLE 1

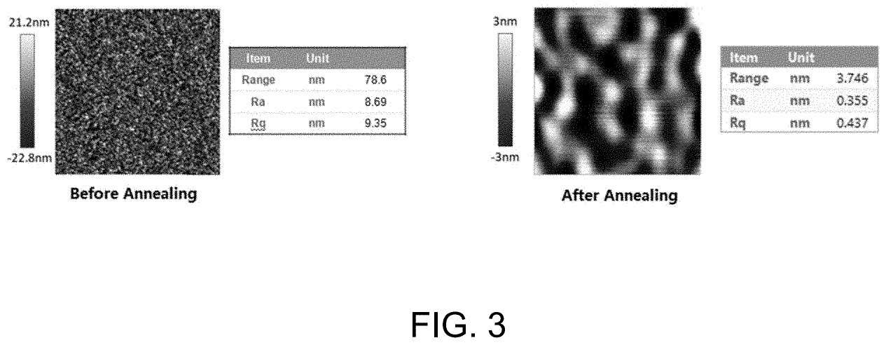

The left figure of FIG. 3 is a non-contact scanning image of a SOI wafer surface AFM 10 μm×10 μm obtained by the Smart-cut process. The wafer has a surface roughness of 93.5 Å.

The above wafer was loaded into a CVD reaction furnace at the temperature of 800° C. in an atmosphere of pure Ar, and this was maintained for 5 min. Then, the atmosphere was switched to a mixed atmosphere of Ar+2.5% H₂, and the temperature was increased at the heating rate of 5° C./min. When the temperature reached the target temperature, an annealing process was initiated, the atmosphere was switched to pure Ar, the temperature was 1100° C., the annealing process was continued for 40 min. The atmospheric environment remained to be pure Ar after the annealing process was completed. Later, the temperature was decreased to below 600° C. at the cooling rate of 0.5° C./s to 10° C./s before the wafer was taken out. The right figure of FIG. 3 is a non-contact scanning image of AFM 10 μm×10 μm after annealing. The wafer has a surface roughness of 4.4 Å after annealing.

What is claimed is:

1. A method for treating a wafer surface, comprising:
loading a wafer with a SOI structure into a vertical furnace tube at a temperature of 500° C. to 800° C. in an atmosphere of pure Ar, and maintaining this for 1 min to 10 min; then switching the atmosphere to a mixed atmosphere of Ar+n % H₂ and starting to heat up, wherein n is less than 10; increasing the temperature to a range of 1050° C. to 1250° C. followed by annealing for 1 min to 120 min; maintaining the atmosphere to be pure Ar after the annealing process is completed, and taking out the wafer when the temperature is decreased to below 700° C.

2. The method according to claim 1, wherein the heating rate is 0.5° C./min to 20° C./min.

3. The method according to claim 1, wherein after the temperature is increased to a range of 1050° C. to 1250° C., the mixed atmosphere Ar+n % H₂ in the heating-up stage is maintained, or switched to a pure Ar atmosphere.

4. The method according to claim 1, wherein the cooling rate of decreasing the temperature to room temperature is 0.5° C./min to 10° C./min.

5. The method according to claim 1, wherein thinning by oxidation is carried out after the annealing process is completed, and then the temperature is decreased to room temperature.

6. The method according to claim 5, wherein the oxidation temperature is in a range of 800° C. to 1000° C., and the cooling rate of decreasing the temperature to oxidation temperature is 1° C./min to 10° C./min.

7. The method according to claim 5, wherein the atmosphere for thinning by oxidation is dry oxygen, wet oxygen, or a combination of dry oxygen and wet oxygen.

8. The method according to claim 5, wherein after thinning by oxidation, the surface oxidized layer is removed in a HF solution with a concentration of less than 20%.
